(19) United States
(12) Patent Application Publication
(10) Pub. No.: US 2024/0310809 A1
(43) Pub. Date: Sep. 19, 2024

(54) CONTROL DEVICE, CONTROL METHOD, STORAGE MEDIUM, AND ARTICLE MANUFACTURING METHOD

(71) Applicant: CANON KABUSHIKI KAISHA, Tokyo (JP)

(72) Inventor: RYO NAWATA, Tochigi (JP)

(21) Appl. No.: 18/595,891

(22) Filed: Mar. 5, 2024

(30) Foreign Application Priority Data
Mar. 14, 2023 (JP) 2023-039418

(51) Int. Cl. G05B 19/404; G05B 11/38

(52) U.S. Cl. CPC G05B 19/404; G05B 11/38; G05B 2219/49176

(57) ABSTRACT

In order to control motions of a first movable part and a second movable part in which the first movable part is mounted, the control device includes: a first measuring unit configured to measure the motion of the first movable part; a first compensation unit configured to generate a first amount of operation based on an output of the first measuring unit to control the motion of the first movable part; a second compensation unit configured to generate a second amount of operation based on the output of the first measuring unit to control the motion of the first movable part; a first computing unit configured to generate an amount of operation for driving the first movable part based on an output of the first compensation unit and an output of the second compensation unit; a second measuring unit configured to measure the motion of the second movable part; a third compensation unit configured to generate a third amount of operation based on an output of the second measuring unit to control the motion of the second movable part; and a control unit configured to determine parameter values for generating the second and third amounts of operation in the second and third compensation units using machine learning by starting the machine learning at different timings.

### BACKGROUND OF THE INVENTION

### Field of the Invention

The present invention relates to a control device, a control method, a storage medium, and an article manufacturing method.

### Description of the Related Art

A classical controller such as a proportional-integral-differential (PID) controller is often used as a control device for controlling physical quantities of a target object. In recent years, a control system which is constructed using machine learning (which includes reinforcement learning) has often been used in addition to a control system based on classical control theories or modern control theories.

In Japanese Patent Laid-Open No. 2019-71405, a feedback control device using both a control system not including machine learning and a control system including machine learning is used, and a control deviation of a target object which cannot be fully compensated for by only the control system not including machine learning is decreased using the control system based on machine learning.

When a stage (a first movable part) is mounted on a main structure (a second movable part) as disclosed in Japanese Patent Laid-Open No. 2019-71405, there is a likelihood that vibration from pipes, ducts, or the like will be transferred thereto. Accordingly, when a decrease in vibration of the stage based on machine learning is performed using the method described in Japanese Patent Laid-Open No. 2019-71405, vibration of high frequencies (100 Hz or higher) in the main structure may be excited and thus vibration of stage equipment may not be able to be decreased.

### SUMMARY OF THE INVENTION

According to an aspect of the present invention, there is provided a control device for controlling motions of a first movable part and a second movable part in which the first movable part is mounted, the control device including at least one processor or circuit configured to function as: a first measuring unit configured to measure the motion of the first movable part; a first compensation unit configured to generate a first amount of operation based on an output of the first measuring unit to control the motion of the first movable part; a second compensation unit configured to generate a second amount of operation based on the output of the first measuring unit to control the motion of the first movable part; a first computing unit configured to generate an amount of operation for driving the first movable part based on an output of the first compensation unit and an output of the second compensation unit; a second measuring unit configured to measure the motion of the second movable part; a third compensation unit configured to generate a third amount of operation based on an output of the second measuring unit to control the motion of the second movable part; and a control unit configured to determine parameter values for generating the second amount of operation and the third amount of operation in the second compensation unit and the third compensation unit using machine learning and to start the machine learning in the second compensation unit and the machine learning in the third compensation unit at different timings.

Further features of the present invention will become apparent from the following description of embodiments with reference to the attached drawings.

### BRIEF DESCRIPTION OF THE DRAWINGS

FIG. 1 is a diagram schematically illustrating an example of a configuration of imprint equipment 1000 according to a first embodiment.

FIG. 2 is a functional block diagram illustrating an example of a configuration of a stage control unit of imprint equipment which is a drive control device according to the first embodiment.

FIG. 3 is a functional block diagram illustrating an example of a configuration of an NN controller 220 according to the first embodiment.

FIG. 4 is a functional block diagram illustrating an example of a configuration of an NN 216 according to the first embodiment.

FIG. 5 is a functional block diagram illustrating an example of a configuration of a control unit of a main structure according to the first embodiment.

FIG. 6 is a functional block diagram illustrating an example of a configuration of an NN controller 252 according to the first embodiment.

FIG. 7 is a flowchart illustrating an example of a method of adjusting an NN 216 and an NN 256 for realizing a drive control method according to the first embodiment.

FIG. 8 is a functional block diagram illustrating an example of a configuration of a stage control unit according to a second embodiment.

### DESCRIPTION OF THE EMBODIMENTS

Hereinafter, with reference to the accompanying drawings, favorable modes of the present invention will be described using Embodiments. In each diagram, the same reference signs are applied to the same members or elements, and duplicate description will be omitted or simplified.

A control target which will be described below is not limited to embodiments, and a type of the control target is not particularly limited as long as it is a physical quantity which can be feedback-controlled.

Representative control targets will be described below. Examples thereof include a displacement, a speed, and an acceleration in a forward moving direction and a rotating direction of an object and a flow volume, a flow rate, and a pressure of gas or fluid. Examples thereof include a liquid level height of a fluid, a temperature of an object, a gas, or a liquid, and a current, a voltage, and electric charge of an electrical circuit or the like. Examples thereof include a magnetic flux and a magnetic flux density in a magnetic field and a sound pressure of a sound field.

These physical quantities are measured by a detection unit using a known detector (sensor) and measured values are input to a control device. A control quantity drive unit is an active element for changing a physical quantity which is a control target, and motors, piezoelectric elements, and the like are used when the control target is a position, a speed, or an acceleration of an object. In an electric system, a driver for operating a current or a voltage or the like is used.

### First Embodiment

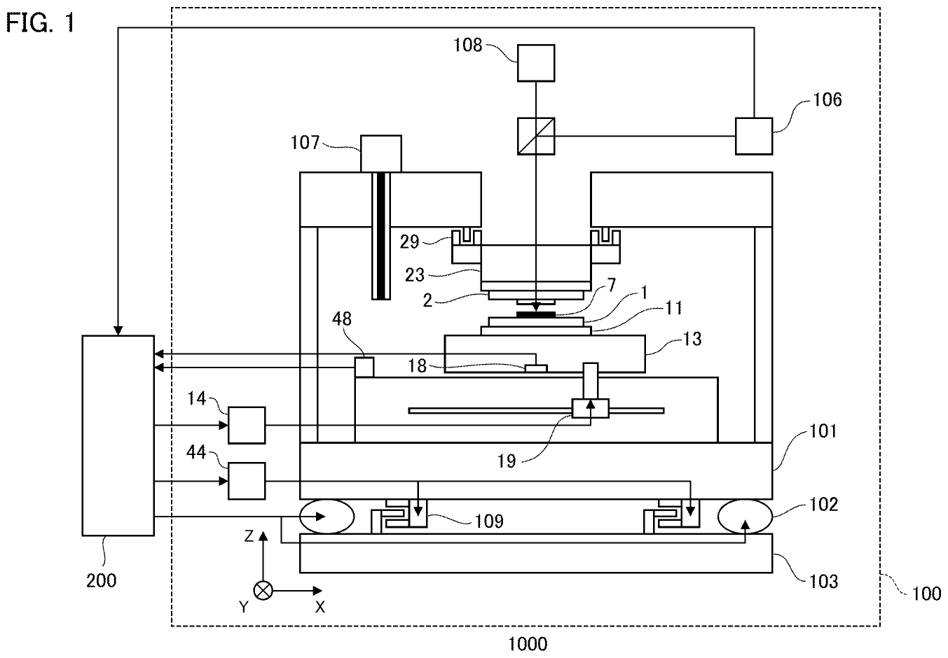

In a first embodiment, imprint equipment which is shaping equipment is described as an example of a main system in which a stage is mounted. FIG. 1 is a diagram schematically illustrating an example of a configuration of imprint equipment 1000 according to the first embodiment.

The imprint equipment 1000 is a device including a formation unit that forms a pattern of a cured product onto which an uneven pattern of a mold 2 has been transferred by bringing the mold 2 into contact with an imprint material 7 supplied onto a substrate 1 and applying curing energy to the imprint material 7.

That is, the imprint equipment 1000 cures the imprint material 7, for example by irradiating the imprint material 7 with light in a state in which the imprint material 7 is supplied onto the substrate 1 and the mold 2 in which an uneven pattern is formed is in contact with the imprint material 7 on the substrate 1. Then, by separating the mold 2 and the substrate 1 to remove (release) the mold 2 from the cured imprint material 7, the pattern of the mold 2 can be transferred to the imprint material 7 on the substrate 1.

This series of processes is referred to as an imprinting process and is performed on each of a plurality of shot areas on the substrate 1. That is, when the imprinting process is performed on each of a plurality of shot areas on one substrate 1, the imprinting process is repeatedly performed according to the number of shot areas of the substrate 1.

The imprint equipment 1000 includes a mechanical structure 100 and a control unit 200. The substrate 1 which is a target object is held on a stage 13 which is a first movable part by a substrate chuck 11. The stage 13 moves the substrate 1 with sufficient strokes in an X direction and a Y direction such that the imprinting process is performed on each shot area of the whole surface of the substrate 1.

The stage 13 has enough strokes in the X direction and the Y direction to move the substrate 1 to an exchange position at which the substrate 1 is loaded and unloaded using a substrate exchange hand which is not illustrated. The stage 13 is guided to be movable in the X direction, for example, using a hydrostatic guide, and a driving force in the X direction is applied thereto by a linear motor 19 (a drive unit).

On the stage 13, a Y stage which is not illustrated is configured to be movable in the Y direction using a hydrostatic guide and a linear motor. The linear motor 19 is driven by a current driver 14. A moving unit for moving the substrate 1 which is a movement target object includes the stage 13, the linear motor 19, and a drive circuit. The configuration of the stage 13 is not limited thereto, and a high-accuracy positioning stage which is used as a stage of exposure equipment can be used.

The position in the X direction of the stage 13 is measured by a stage position measuring unit 18. The stage position measuring unit 18 is, for example, a linear encoder and includes scales (not illustrated) formed on a main structure 101, a head on the stage 13, and a computing unit. Here, the main structure 101 serves as a second movable part in which the stage 13 which is a first movable part is mounted.

Similarly, for example, a linear encoder for the Y axis which is not illustrated and which measures a position in the Y direction is also provided. A combination of an interferometer provided in the main structure 101 and a reflective mirror provided on the stage 13 may be used to measure a position of the stage 13.

The stage position measuring unit 18 serves as a first measuring unit and performs a first measuring step of measuring a motion of the stage 13 which is the first movable part. Here, the first measuring unit includes a measuring instrument for measuring a position of the first movable part, but is not limited to the stage position measuring unit 18.

A photo-curable resin serving as the imprint material 7 is supplied to a position of a shot area on the substrate 1 by a dispenser 107. At this time, the stage 13 determines an application position of the imprint material 7 on the substrate 1 just below the dispenser 107. Subsequently, the stage 13 moves just below the mold 2 on which a minute pattern is formed and determines the application position of the imprint material 7 on the substrate 1. The mold 2 is held by an imprint head 23.

The imprint head 23 can move the mold 2 in a Z direction using an actuator 29. Until the position of a shot area on the substrate 1 moves to just below the mold 2, the mold 2 waits at a position above the substrate 1 in the Z direction. When the shot position on the substrate 1 is positioned just below the mold 2, the mold 2 is moved downward by the imprint head 23 to press a patterned part of the mold 2 on the imprint material 7.

When a semiconductor device or the like is manufactured using the imprint equipment, alignment with a previous layer is important for transferring the pattern of the mold 2 onto the imprint material 7 on the substrate 1. This alignment is called alignment. An alignment detector 106 optically detects alignment marks (not illustrated) provided on both the substrate 1 and the mold 2, performs image processing thereon, and detects misalignment of the alignment marks in the X and Y directions (misalignment between the substrate 1 and the mold 2).

Information of the misalignment is sent to a control unit 200 which will be described later, and alignment is performed by correcting X and Y positions of the stage 13 or the imprint head 23. When the alignment is completed, the imprint material 7 is irradiated with exposure light from an illumination system 108 to cure the imprint material 7. After the imprint material 7 has been cured, the imprint head 23 moves the mold 2 upward to release the mold 2 from the imprint material 7 on the substrate 1.

Through this imprinting process (imprinting steps), a pattern corresponding to the pattern formed on the mold 2 is transferred to the imprint material 7 on the substrate 1. Similarly, the imprinting process is repeatedly performed while changing the shot area, and the stage 13 moves to the substrate exchange position when the imprinting process on all the shot areas on one substrate is completed. Then, the substrate exchange hand which is not illustrated recovers the substrate on which the imprinting process has been completed and supplies a new substrate.

The main structure 101 is installed on a floor 103 via an anti-vibration mechanism 102 with three legs or four legs using air springs or the like. The anti-vibration mechanism 102 serves as both a support mechanism and an actuator, and frequency characteristics thereof have integral characteristics. A linear motor 109 is additionally attached to the main structure 101 to apply forces in directions of six axes to the main structure 101.

An accelerometer 48 is attached to the main structure 101 to measure acceleration in six-axis directions of the main structure 101. Here, the accelerometer 48 serves as a second measuring unit and performs a second measuring step of measuring a motion of the main structure 101 which is a second movable part. The second measuring unit includes the accelerometer 48, but is not limited to the accelerometer 48.

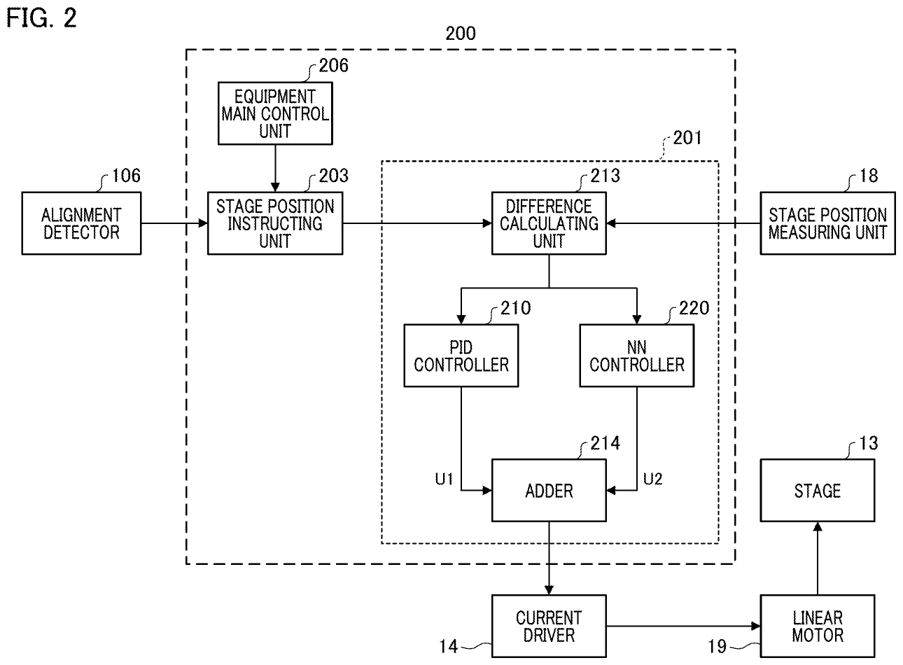

The acceleration of the main structure 101 measured by the accelerometer 48 is sent to the control unit 200. Reference sign 14 denotes a current driver that controls a current value flowing in a coil of the linear motor 19, and reference sign 44 denotes a current driver for controlling a current value flowing in a coil of the linear motor 109. FIG. 2 is a functional block diagram illustrating an example of a configuration of a stage control unit of the imprint equipment as a drive control device according to the first embodiment. The control unit 200 includes a CPU which is a computer and controls operations of constituents of the imprint equipment based on a computer program stored in a memory which is a storage medium.

The constituents such as the control unit 200 illustrated in FIG. 2 serve as a part of a drive control device. The control unit 200 also serves as a control device that controls motions of the stage 13 and the main structure 101.

Some of the functional blocks illustrated in FIG. 2 are realized by causing the CPU which is a computer included in the control unit 200 of the imprint equipment to execute a computer program stored in a memory which is a storage medium which is not illustrated.

Some or all of the functional blocks may be realized by hardware. A dedicated circuit (ASIC), a processor (a reconfigurable processor or a DSP), or the like can be used as the hardware.

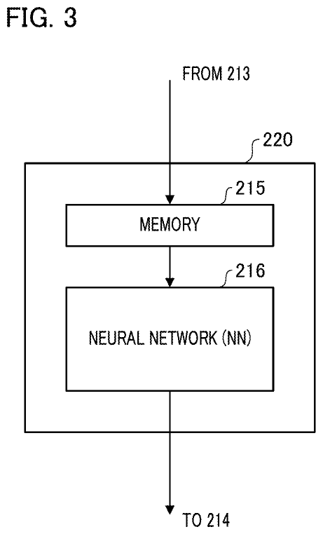

The functional blocks illustrated in FIG. 2 may not be provided in the same housing, but may be constituted by different devices connected to each other via a signal line. The above description with reference to FIG. 2 is true of FIGS. 3 to 6 and FIG. 8.

An equipment main control unit 206 controls the imprint equipment as a whole and includes a CPU which is a computer and a memory which is a storage medium. The equipment main control unit 206 performs sequence management of operations performed by the imprint equipment 1000 or control of the stage control unit 201 or another control unit which is not illustrated by executing a computer program stored in the memory.

A stage position instructing unit 203 acquires and stores a target value of the position of the stage 13 from the equipment main control unit 206 and sends the target value to the stage control unit 201. Misalignment information between the substrate 1 and the mold 2 from the alignment detector 106 is input to the stage position instructing unit 203 and is reflected in the target value of the position of the stage 13. The stage position measuring unit 18 measures the position of the stage 13 every sampling time and sends the measured stage position to the stage control unit 201.

In the stage control unit 201, a difference calculating unit 213 calculates a difference (hereinafter referred to as a stage difference) between the stage position (measured value) sent from the stage position measuring unit 18 and the target value of the position of the stage 13 sent from the stage position instructing unit 203.

A PID controller 210 receives information on the stage difference as an input and outputs an amount of operation U1 (a first amount of operation) of the stage 13. Here, the PID controller 210 serves as a first compensation unit and performs a first compensation step of generating the first amount of operation (U1) based on the output of the stage position measuring unit 18 which is the first measuring unit to control the motion of the stage 13 which is the first movable part.

In the first embodiment, the stage difference is also sent to an NN controller 220 as illustrated in FIG. 2. The NN controller 220 outputs an amount of operation U2 (a second amount of operation) for decreasing the stage difference. NN is an abbreviation to neural network.

That is, in the first embodiment, the PID controller 210 serves as a position feedback control unit, and the NN controller 220 has a function of further decreasing the stage difference which cannot be fully compensated for by the PID controller 210. Here, the NN controller 220 serves as a second compensation unit and performs a second compensation step of generating the second amount of operation (U2) based on the output of the first measuring unit to control the motion of the stage 13 which is the first movable part.

The stage difference may pass through a cutoff filter (not illustrated) for removing a predetermined frequency component before it is sent to the NN controller 220. A low-pass filter, a high-pass filter, a band-pass filter, or the like can be used as the cutoff filter.

The stage difference may be subjected to a process of thinning out a signal in a predetermined cycle by a sampling unit which is not illustrated. That is, a sampling unit for thinning out a difference between a predetermined target value and the output of the first measuring unit in a predetermined cycle and then supplying the thinned-out difference to the NN controller 220 which is the second compensation unit.

Accordingly, since information of high frequencies is removed from the stage difference, it is possible to prevent excitation of high-frequency waves. Since an amount of information of low frequencies can be increased, it is possible to more effectively decrease a low-frequency component of the stage difference.

FIG. 3 is a functional block diagram illustrating an example of a configuration of the NN controller 220 according to the first embodiment. The NN controller 220 includes a memory 215 that stores a history of the stage difference and a neural network (NN) 216. A predetermined number of (N, where N is a natural number) memories are provided as the memory 215 and store the stage difference corresponding to the latest N steps.

Parameters such as network weights of the NN 216 are adjusted such that, when the stage difference corresponding to N steps in the memory 215 is input to an input layer, an output layer thereof outputs a value corresponding to a correction value of the output (the amount of operation U1) of the PID controller 210.

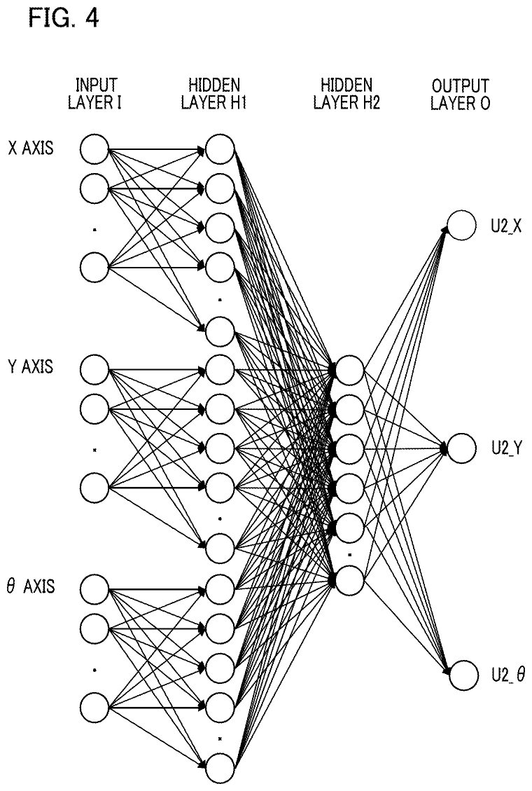

FIG. 4 is a functional block diagram illustrating an example of a configuration of the NN 216 according to the first embodiment. As illustrated in FIG. 4, the NN 216 includes, for example, an input layer I, a hidden layer H1, a hidden layer H2, and an output layer O. The network parameters of the NN 216 are adjusted in advance, for example, using a network parameter adjusting method based on reinforcement learning, but the network parameters may be adjusted using any machine learning method.

The NN 216 may be a network (a policy network) that directly outputs a value corresponding to a dimension of an indicated value or may be a network (an action value network) that calculates a value of an indicated value. When the NN 216 is an action value network, a selector for selecting an action with a maximum value is added to the stage subsequent to the NN, and an indicated value selected by the selector becomes the output (the amount of operation U2) of the NN controller 220.

An adder 214 adds the output value (the amount of operation U1) generated by the PID controller 210 and the output value (the amount of operation U2) generated by the NN controller 220. The output of the adder 214 is converted to an analog signal by a D/A converter which is not illustrated and is sent and input to the current driver 14.

Here, the adder 214 serves a first computing unit and performs a first computing step of generating an amount of operation for driving the first movable part (the stage 13) based on the output (U1) of the first compensation unit and the output (U2) of the second compensation unit.

The current driver 14 controls a current value flowing in a coil of the linear motor 19 according to the output of the adder 214. Since a thrust of the linear motor 19 is proportional to a current flowing in the coil, a force corresponding to the added value of the PID controller 210 and the NN controller 220 is applied to the stage 13.

As described above, in the first embodiment, the output (the amount of operation U2) of the NN controller 220 with the stage difference as an input is added to the output value (the amount of operation U1) of the PID controller 210. Accordingly, it is possible to decrease a stage difference which cannot be fully compensated for by the PID controller 210.

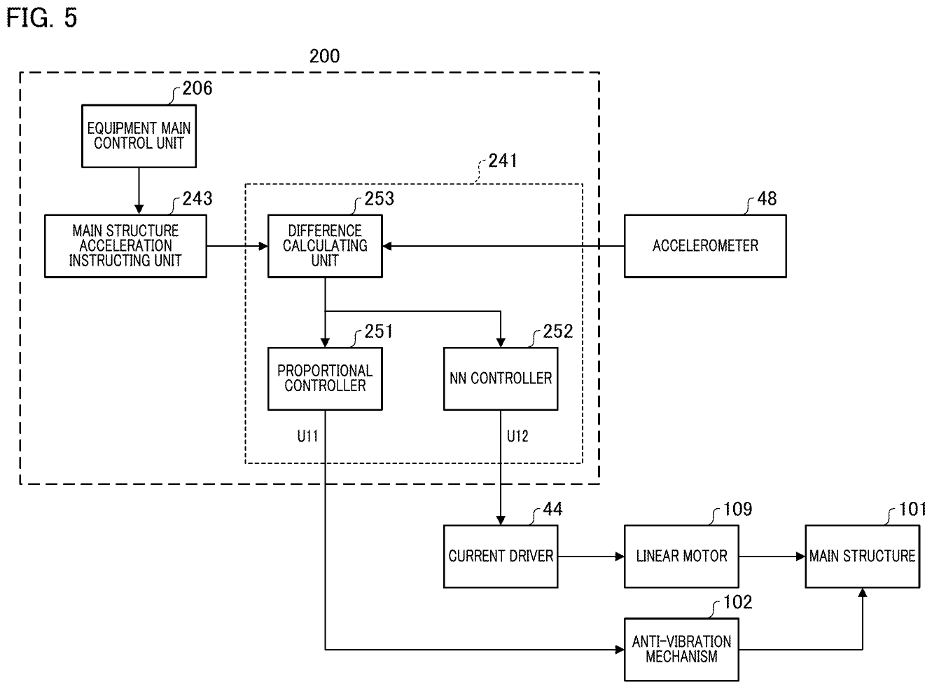

FIG. 5 is a functional block diagram illustrating an example of a configuration of a control unit of the main structure according to the first embodiment. The constituents such as the control unit 200 illustrated in FIG. 5 serve as a part of a drive control device. Reference sign 241 denotes a main structure control unit, and reference sign 243 denotes a main structure acceleration instructing unit.

In the main structure control unit 241, a difference calculating unit 253 calculates a difference (hereinafter, referred to as a main-structure acceleration difference) between the output of the accelerometer 48 and a target value of the acceleration of the main structure 101 sent from the main structure acceleration instructing unit 243 and sends the calculated difference to a proportional controller 251.

The proportional controller 251 receives information on a main-structure acceleration difference as an input and supplies an amount of operation U11 (a fourth amount of operation) of the main structure 101 to the anti-vibration mechanism 102. Here, the proportional controller 251 serves as a fourth compensation unit and generates the fourth amount of operation (U11) based on the target value for controlling the motion of the main structure 101 which is the second movable part and the output of the second measuring unit. The proportional controller 251 which is the fourth compensation unit drives the second movable part based on the fourth amount of operation.

The anti-vibration mechanism 102 has integral characteristics, and a feedback control unit including the proportional controller 251 serves to control the speed of the main structure 101 in a feedback manner such that a peak of a specific frequency of the anti-vibration mechanism 102 is attenuated. In this way, the proportional controller 251 which is the fourth compensation unit controls the anti-vibration mechanism 102 for suppressing vibration of the second movable part.

The main-structure acceleration difference is also sent to the NN controller 252. The NN controller 252 outputs an amount of operation U12 (a third amount of operation) for decreasing the main-structure acceleration difference. The main-structure acceleration difference may pass through a cutoff filter (not illustrated) for removing a predetermined frequency component before it is sent to the NN controller 252. A low-pass filter, a high-pass filter, a band-pass filter, or the like can be used as the cutoff filter.

Here, the NN controller 252 serves as a third compensation unit and performs a third compensation step of generating the third amount of operation (U12) based on the output of the second measuring unit to control the motion of the main structure 101 which is the second movable part. The third compensation unit controls the motion of the main structure 101 which is the second movable part by driving a linear motor 109 which is a motor other than that of the anti-vibration mechanism 102.

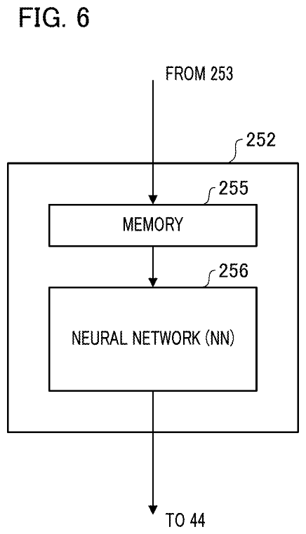

FIG. 6 is a functional block diagram illustrating an example of a configuration of the NN controller 252 according to the first embodiment, where the configuration of the NN controller 252 is the same as the configuration of the NN controller 220. Network parameters of the NN 256 are adjusted in advance, for example, using a network parameter adjusting method based on reinforcement learning, but the network parameters of the NN controller 252 may be adjusted using any machine learning method.

The amount of operation U12 is converted to an analog signal by a D/A converter which is not illustrated and is supplied to a current driver 44. The current driver 44 controls a current value flowing in a coil of the linear motor 109 according to the amount of operation U12.

Since a thrust of the linear motor 109 is proportional to a current flowing in the coil, a force corresponding to the amount of operation U12 is applied to the main structure 101. Accordingly, since a force for decreasing the main-structure acceleration difference is applied to the main structure 101, it is possible to suppress vibration of the main structure 101.

As described above, the control unit 200 according to the first embodiment includes the NN controller 220 that decreases the stage difference and the NN controller 252 that suppresses vibration of the main structure 101. The NN 216 of the NN controller 220 and the NN 256 of the NN controller 252 are adjusted in advance using machine learning.

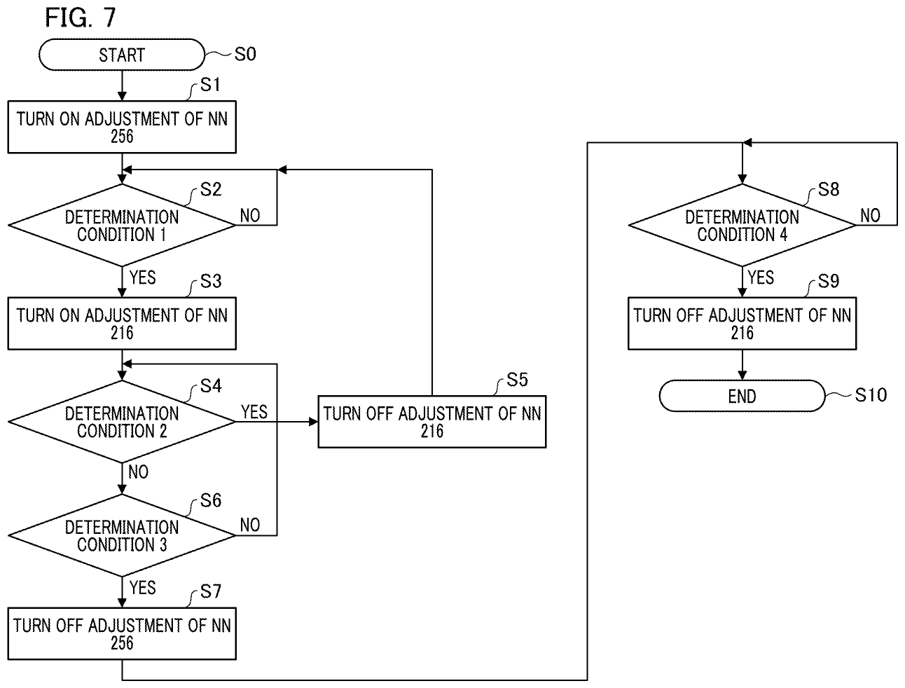

FIG. 7 is a flowchart illustrating an example of a method of adjusting the NN 216 and the NN 256 for realizing a drive control method according to the first embodiment. Operations of the steps in the flowchart illustrated in FIG. 7 are sequentially performed by causing a CPU or the like which is a computer in the equipment main control unit 206 to execute a computer program stored in a memory.

The flowchart illustrated in FIG. 7 is started in Step S0, and adjustment of the NN 256 is turned on in Step S1. Then, in Step S2, it is determined whether determination condition 1 is satisfied. Determination condition 1 is, for example, a condition that the acceleration of the main structure 101 reaches a predetermined threshold value A1.

The magnitude of the threshold value A1 is set to, for example, about ⅔ of the acceleration of the main structure 101 before the adjustment of the NN 216 is turned on. Step S2 is repeated until determination condition 1 of Step S2 is satisfied, and adjustment of the NN 216 is turned on in Step S3 when the determination result of Step S2 is YES. That is, when the output of the second measuring unit is equal to or less than a predetermined threshold value, machine learning for determining parameters of the NN controller 220 which is the second compensation unit is started.

In this way, in the present embodiment, the equipment main control unit 206 determines the parameter values for generating the second amount of operation and the third amount of operation in the second compensation unit and the third compensation unit using machine learning. The equipment main control unit 206 starts the machine learning in the second compensation unit and the machine learning in the third compensation unit at different timings.

Then, it is determined in Step S4 whether determination condition 2 is satisfied. Determination condition 2 is, for example, a condition that the acceleration of the main structure 101 is equal to or greater than a predetermined threshold value A2. The magnitude of the threshold value A2 in Step S4 is set to, for example, the same as the acceleration of the main structure 101 before adjustment of NN 256 is turned on.

It is preferable that the threshold value A2 of determination condition 2 in Step S4 be set to be greater than the threshold value A1 of determination condition 1 in Step S2, that is, A2>A1 be satisfied. When determination condition 2 in Step S4 is satisfied, adjustment of the NN 216 is turned off in Step S5.

In this way, in the present embodiment, when the acceleration of the main structure 101 increases after adjustment of the NN 216 has been turned on in Step S3, adjustment of the NN 216 is turned off in Step S5.

That is, when the output of the second measuring unit is equal to or greater than a predetermined threshold value in determination condition 2, machine learning for determining parameters of the second compensation unit is turned off. After the acceleration of the main structure 101 has decreased, adjustment of the NN 216 can be restarted in Step S3.

Steps S4 and S5 are processes for a safety function of stopping training of the NN 216 when the acceleration of the main structure 101 gets worse due to starting of training of the NN 216.

On the other hand, when the determination result of Step S4 is NO, the process flow proceeds to Step S6 and it is determined in Step S6 whether determination condition 3 is satisfied. Determination condition 3 is, for example, a condition that the acceleration of the main structure 101 reaches a predetermined threshold value A3.

The magnitude of the threshold value A3 is set to, for example, about ⅓ of the acceleration of the main structure 101 before the adjustment of the NN 216 is turned on. It is preferable that A2>A1>A3 be satisfied. When determination condition 3 in Step S6 is satisfied, adjustment of the NN 256 is turned off in Step S7.

Then, in Step S8, it is determined whether determination condition 4 is satisfied. Determination condition 4 is a condition that the stage difference is equal to or less than a predetermined threshold value B1. The threshold value B1 is set to, for example, ⅓ of the stage difference before adjustment of the NN 216 is turned on.

When determination condition 4 in Step S8 is satisfied, adjustment of the NN 216 is turned off in Step S9, and the flowchart illustrated in FIG. 7 ends in Step S10. Instead of turning off adjustment of the NN 256 in Step S7, adjustment of the NN 256 may be turned off when the determination result of Step S8 is YES.

In the aforementioned flowchart, the acceleration of the main structure 101 is compared with the predetermined threshold values A1 to A3 in determination conditions 1, 2, and 3, but the stage difference or the output of the alignment detector 106 may be compared with threshold values.

For example, when the output of the first measuring unit is equal to or less than a predetermined threshold value in determination condition 1, machine learning for determining parameters of the NN controller 220 which is the second compensation unit may be started. Alternatively, when the output of the third measuring instrument is equal to or less than a predetermined threshold value in determination condition 1, machine learning for determining parameters of the second compensation unit may be started.

When the output of the first measuring unit is equal to or greater than a predetermined threshold value in determination condition 2, machine learning for determining parameters of the second compensation unit may be turned off. Alternatively, when the output of the third measuring instrument is equal to or greater than a predetermined threshold value in determination condition 2, machine learning for determining parameters of the second compensation unit may be turned off.

Steps S1 to S10 serve as a control step of determining the parameter values for generating the second amount of operation and the third amount of operation using machine learning in the second compensation step and the third compensation step. In the control step, the machine learning in the second compensation and the machine learning in the third compensation step are started at different timings.

In the present embodiment, adjustment of the NN 256 for suppressing vibration of the main structure 101 is performed earlier than adjustment of the NN 216 for decreasing the stage difference. That is, the control unit starts the machine learning for determining the parameters in the third compensation unit earlier than the machine learning for determining the parameters in the second compensation unit.

Accordingly, it is possible to perform adjustment of the NN 216 for decreasing the stage difference in a state in which vibration of the main structure 101 is suppressed.

When adjustment of the NN 216 for decreasing the stage difference is performed without suppressing vibration of the main structure 101, a high-frequency mode of the stage difference is excited and thus the NN 216 capable of sufficiently decreasing the stage difference may not be obtained. On the other hand, according to the present embodiment, it is possible to more stably decrease the stage difference.

### Second Embodiment

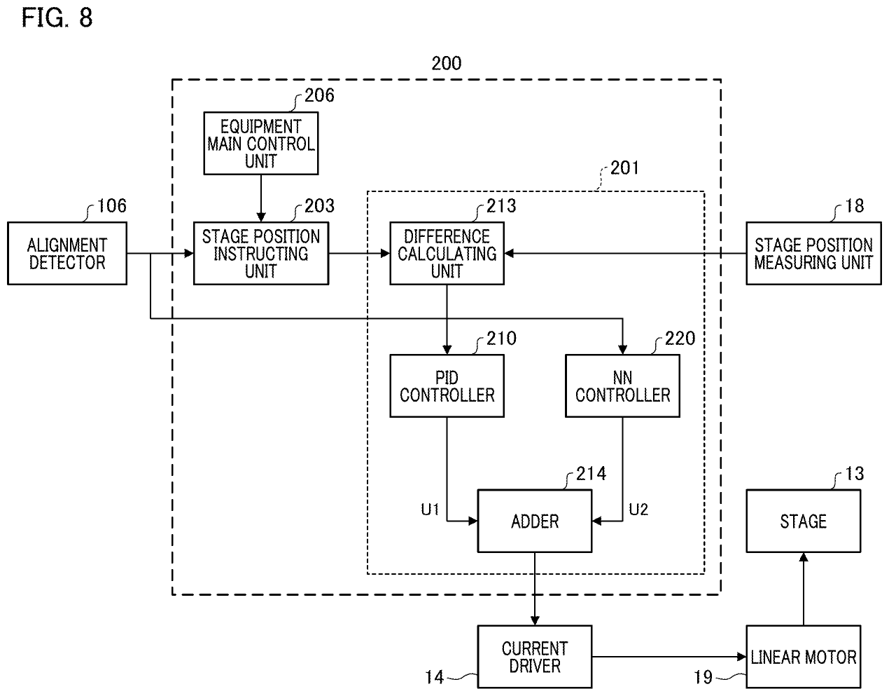

FIG. 8 is a functional block diagram illustrating an example of a configuration of a control unit for a stage according to a second embodiment. The stage difference is set to the NN controller 220 in the first embodiment, but the output of the alignment detector 106 is sent to the NN controller 220 in the second embodiment, both of which are different.

That is, the stage decrease is decreased by the NN controller 220 in the first embodiment, but the output of the alignment detector 106 for detecting misalignment between the substrate 1 and the mold 2 is decreased by the NN controller 220.

In the second embodiment, the first measuring unit includes a stage position measuring unit which is a first measuring instrument and an alignment detector which is a third measuring instrument. The PID controller 210 which is the first compensation unit generates a first amount of operation (U1) based on the output of the first measuring instrument, and the NN controller 220 which is the second compensation unit generates a second amount of operation (U2) based on the output of the third measuring instrument.

The output of the alignment detector 106 may pass through a cutoff filter (not illustrated) for removing a predetermined frequency component before it is sent to the NN controller 220. A low-pass filter, a high-pass filter, a band-pass filter, or the like can be used as the cutoff filter.

The output of the alignment detector 106 may be subjected to a process of thinning out a signal in a predetermined cycle by a sampling unit which is not illustrated. Accordingly, since information of high frequencies is removed from the output of the alignment detector 106, it is possible to prevent excitation of high-frequency waves and to increase an amount of information of low frequencies. Accordingly, it is possible to more effectively decrease a low-frequency component of the output of the alignment detector 106.

The flowchart according to the second embodiment may be substantially the same as in FIG. 7, except that it is determined whether the output of the alignment detector 106 reaches a predetermined threshold value C1 in determination condition 4 in Step S8 of the adjustment method illustrated in FIG. 7.

The magnitude of the threshold value C1 is set to, for example, about ⅓ of the output of the alignment detector 106 before the adjustment of the NN 216 is turned on. In this way, in the present embodiment, when the output of the alignment detector 106 which is the third measuring instrument is equal to or less than a predetermined threshold value, machine learning for determining parameters of the NN controller 220 which is the second compensation unit is turned off.

### Third Embodiment

In the first embodiment and the second embodiment, it is assumed that a mold including a patterned part is used for imprint equipment which is shaping equipment.

However, the aforementioned main system can be applied to planarization equipment for planarizing a resin on a substrate which is a target object using a mold without a patterned part. That is, the shaping equipment may include imprint equipment or planarization equipment as long as it can shape a composition on a substrate using a mold.

The first embodiment and the second embodiment can also be applied to, for example. a control system for measuring equipment or processing equipment in addition to lithography equipment such as imprint equipment. The lithography equipment includes exposure equipment that forms a pattern on a substrate using a mask. The measuring equipment may include a stage for controlling a position of a target object and a measuring unit configured to measure the target object of which the position has been controlled by the stage, where a contact probe, a contactless interferometer, or the like may be used as the measuring unit.

The processing equipment includes a stage for controlling a position of a target object and a processing unit configured to process the target object of which the position has been controlled by the stage. For example, a bite or a laser may be used as the processing unit. In this way, the drive control device according to the first to third embodiments is included in one of shaping equipment, measuring equipment, processing equipment, and lithography equipment.

(Article manufacturing method)

An article manufacturing method using the drive control device according to the aforementioned embodiments can be suitably used to manufacture an article such as a micro device such as a semiconductor device or a device having a fine structure.

The article manufacturing method includes a step of forming a pattern or a flat surface on an imprint material supplied (applied) onto a substrate using the imprint equipment (the imprint method) and a processing step of processing the substrate on which the pattern or the flat surface is formed in the aforementioned step.

This article manufacturing method includes other known steps (oxidation, film formation, deposition, doping, planarization, etching, resist removing, dicing, bonding, packaging, and the like). The article manufacturing method according to the present embodiment is advantageous in at least one of performance, quality, productivity, and production cost of an article in comparison with the related art.

An article manufacturing method for an article (such as a semiconductor IC element, a liquid crystal display element, a color filter, or an MEMS) when the third embodiment is applied to exposure equipment will be described below. The article is manufactured through a step of exposing a substrate (such as a wafer or a glass substrate) coated with a photoresist using the exposure equipment, a step of developing the substrate (the photoresist), and steps of processing the developed substrate using other known manufacturing steps.

The other known steps include etching, resist removing, dicing, bonding, and packaging. According to this manufacturing method, it is possible to manufacture an article with higher quality than in the related art.

While the present invention has been described with reference to exemplary embodiments, it is to be understood that the invention is not limited to the disclosed exemplary embodiments. The scope of the following claims is to be accorded the broadest interpretation to encompass all such modifications and equivalent structures and functions.

In addition, as a part or the whole of the control according to the embodiments, a computer program realizing the function of the embodiments described above may be supplied to the control device or the like through a network or various storage media. Then, a computer (or a CPU, an MPU, or the like) of the control device or the like may be configured to read and execute the program. In such a case, the program and the storage medium storing the program configure the present invention.

For example, the present invention may be realized using at least one processor or circuit configured to function of the embodiments explained above. The present invention may be realized in a distributed processing manner using a plurality of processors.

This application claims the benefit of Japanese Patent Application No. 2023-039418, filed on Mar. 14, 2023, which is hereby incorporated by reference herein in its entirety.

What is claimed is:

1. A control device for controlling motions of a first movable part and a second movable part in which the first movable part is mounted, the control device comprising at least one processor or circuit configured to function as:
a first measuring unit configured to measure the motion of the first movable part;
a first compensation unit configured to generate a first amount of operation based on an output of the first measuring unit to control the motion of the first movable part;
a second compensation unit configured to generate a second amount of operation based on the output of the first measuring unit to control the motion of the first movable part;
a first computing unit configured to generate an amount of operation for driving the first movable part based on an output of the first compensation unit and an output of the second compensation unit;
a second measuring unit configured to measure the motion of the second movable part;
a third compensation unit configured to generate a third amount of operation based on an output of the second measuring unit to control the motion of the second movable part; and
a control unit configured to determine parameter values for generating the second amount of operation and the third amount of operation in the second compensation unit and the third compensation unit using machine learning and to start the machine learning in the second compensation unit and the machine learning in the third compensation unit at different timings.

2. The control device according to claim 1, wherein the at least one processor or circuit is further configured to function as a sampling unit configured to sample a difference between a predetermined target value and the output of the first measuring unit in a predetermined cycle and then to supply the difference to the second compensation unit.

3. The control device according to claim 1, wherein the control unit starts the machine learning for determining parameters of the third compensation unit earlier than the machine learning for determining parameters of the second compensation unit.

4. The control device according to claim 1, wherein the control unit starts the machine learning for determining parameters of the second compensation unit when the output of the second measuring unit is equal to or less than a predetermined threshold value.

5. The control device according to claim 1, wherein the second measuring unit includes an accelerometer.

6. The control device according to claim 1, wherein the first measuring unit includes a measuring instrument for measuring a position.

7. The control device according to claim 1, wherein the first measuring unit includes a first measuring instrument and a third measuring instrument, the first compensation unit generates the first amount of operation based on an output of the first measuring instrument, and the second compensation unit generates the second amount of operation based on an output of the third measuring instrument.

8. The control device according to claim 7, wherein the machine learning for determining parameters of the second compensation unit is turned off when the output of the third measuring instrument is equal to or greater than a predetermined threshold value.

9. The control device according to claim 7, wherein the machine learning for determining parameters of the second compensation unit is started when the output of the third measuring instrument is equal to or less than a predetermined threshold value.

10. The control device according to claim 1, wherein the machine learning for determining parameters of the second compensation unit is started when the output of the first measuring unit is equal to or less than a predetermined threshold value.

11. The control device according to claim 1, wherein the machine learning for determining parameters of the second compensation unit is turned off when the output of the first measuring unit is equal to or greater than a predetermined threshold value.

12. The control device according to claim 1, wherein the machine learning for determining parameters of the second compensation unit is turned off when the output of the second measuring unit is equal to or greater than a predetermined threshold value.

13. The control device according to claim 1, wherein the at least one processor or circuit is further configured to function as a fourth compensation unit configured to generate a fourth amount of operation based on a target value for controlling the motion of the second movable part and the output of the second measuring unit,
wherein the second movable part is driven based on the fourth amount of operation.

14. The control device according to claim 13, wherein the fourth compensation unit includes a proportional controller,
wherein the proportional controller controls an anti-vibration mechanism for suppressing vibration of the second movable part.

15. The control device according to claim 14, wherein the third compensation unit controls the motion of the second movable part by driving a motor other than that of the anti-vibration mechanism.

16. A control method comprising:
first measuring of measuring a motion of a first movable part;
first compensating of generating a first amount of operation based on an output of the first measuring to control the motion of the first movable part;
second compensating of generating a second amount of operation based on the output of the first measuring to control the motion of the first movable part;
first computing of generating an amount of operation for driving the first movable part based on an output of the first compensating and an output of the second compensating;
second measuring of measuring a motion of a second movable part in which the first movable part is mounted;
third compensating of generating a third amount of operation based on an output of the second measuring to control the motion of the second movable part; and
controlling of determining parameter values for generating the second amount of operation and the third amount of operation in the second compensating and the third compensating using machine learning and starting the machine learning in the second compensating and the machine learning in the third compensating at different timings.

17. A non-transitory computer-readable storage medium configured to store a computer program comprising instructions for executing following processes:
first measuring of measuring a motion of a first movable part;
first compensating of generating a first amount of operation based on an output of the first measuring to control the motion of the first movable part;
second compensating of generating a second amount of operation based on the output of the first measuring to control the motion of the first movable part;
first computing of generating an amount of operation for driving the first movable part based on an output of the first compensating and an output of the second compensating;
second measuring of measuring a motion of a second movable part in which the first movable part is mounted;
third compensating of generating a third amount of operation based on an output of the second measuring to control the motion of the second movable part; and
controlling of determining parameter values for generating the second amount of operation and the third amount of operation in the second compensating and the third compensating using machine learning and starting the machine learning in the second compensating and the machine learning in the third compensating at different timings.

18. An article manufacturing method comprising:
first measuring of measuring a motion of a first movable part;
first compensating of generating a first amount of operation based on an output of the first measuring to control the motion of the first movable part;
second compensating of generating a second amount of operation based on the output of the first measuring to control the motion of the first movable part;
first computing of generating an amount of operation for driving the first movable part based on an output of the first compensating and an output of the second compensating;
second measuring of measuring a motion of a second movable part in which the first movable part is mounted;
third compensating of generating a third amount of operation based on an output of the second measuring to control the motion of the second movable part;
determining parameter values for generating the second amount of operation and the third amount of operation in the second compensating and the third compensating using machine learning and starting the machine learning in the second compensating and the machine learning in the third compensating at different timings;
controlling the motion of the first movable part holding a target object;
performing processing on the target object; and
manufacturing an article using the target object processed in the processing.
